(19) United States
(12) Patent Application Publication
(10) Pub. No.: US 2023/0207420 A1
(43) Pub. Date: Jun. 29, 2023

(54) INTEGRATED CIRCUIT HAVING AN IMPROVED THERMAL INTEGRATED CIRCUIT HAVING AN IMPROVED THERMAL PERFORMANCE

(71) Applicant: TEXAS INSTRUMENTS INCORPORATED, DALLAS, TX (US)

(72) Inventors: Kwang-Soo Kim, Sunnyvale (CA); Vivek Kishorechand Arora, San Jose, CA (US); Woochan Kim, San Jose, CA (US)

(21) Appl. No.: 17/563,789

(22) Filed: Dec. 28, 2021

(51) Int. Cl. H01L 23/373; H01L 29/20; H01L 29/772

(52) U.S. Cl. CPC H01L 23/3738; H01L 23/3731; H01L 29/2003; H01L 29/772

(57) ABSTRACT

An electronic device for use in power related applications includes a multi-layered substrate comprised of a first metal layer, a second metal layer, and an intermediate layer disposed between the first metal layer, and the second metal layer. The first metal layer is partitioned into sections, where each of the sections has a first surface and electrical circuits patterned onto the first surface. A lead frame is attached to outer portions of the first metal layer and a die is attached to the first surface of each of the sections of the first metal layer.

### TECHNICAL FIELD

The present disclosure relates to an electronic device and more specifically, to an integrated circuit that includes a multi-layered substrate having an improved thermal performance.

### BACKGROUND

Thermal performance in integrated circuit (IC) packages with high power ratings (e.g., approximately 3.6-7.0 kW) are dependent on a heat slug or heat spreader in the IC package. The heat slug is a single piece structure in the IC package. Thus, reducing a thermal resistance of the IC package below a desired value is difficult due to the single piece structural configuration of the heat slug. In addition, circuit topologies, power output, and package layout are limited due to the single piece heat slug structure. Finally, the single piece heat slug structure cannot provide external isolation that is required with additional isolation materials such as an isolated thermal interface material or other structures to assemble with external systems or heat sinks.

### SUMMARY

In described examples, an electronic device includes a multi-layered substrate comprised of a first metal layer, a second metal layer, and an intermediate layer disposed between the first metal layer, and the second metal layer. The first metal layer is partitioned into sections where each of the sections has a first surface and electrical circuits patterned into the first surface. A lead frame is attached to the first metal layer and a die is attached to the first surface of each of the sections of the first metal layer.

In another described example, a power converter includes a multi-layered substrate comprised of a first metal layer, a second metal layer, and an intermediate layer disposed between the first metal layer, and the second metal layer. The first metal layer is partitioned into a first section having a first surface, a second section having a first surface, and a third section having a first surface. Electrical circuits are patterned into the first surface of the first section, the first surface of the second section, and the first surface of the third section. A lead frame is attached to outer portions of the first metal layer. A die is attached to the first surface of the first section, the first surface of the second section, and the first section of the third section.

In another described example, a method includes providing a multi-layered substrate, the multi-layered substrate having a first metal layer, a second metal layer, and an intermediate layer disposed between the first metal layer and the second metal layer, the first metal layer partitioned into sections. A lead frame is attached to outer portions of the first metal layer. A die is attached to a first surface of each of the partitioned sections of the first metal layer and wire bonds are attached from the die of each of the partitioned sections to the lead frame. A mold compound is formed over portions of the lead frame, the multi-layered substrate, each die, and the wire bonds.

### BRIEF DESCRIPTION OF THE DRAWINGS

FIGS. 1A and 1B are a plan and side view respectively of an example electronic device having a partitioned substrate.

FIGS. 2A and 2B are a plan view and a side view of another electronic device that includes a partitioned heat slug.

FIGS. 3A and 3B illustrate the thermal performance of the example electronic devices illustrated in FIGS. 1A, 1B, 2A, and 2B.

FIG. 4 is a flow diagram illustrating a method of fabricating the electronic device illustrate in FIGS. 1A and 1B.

### DETAILED DESCRIPTION

Disclosed herein is a system and method of fabricating an electronic device and more specifically and integrated circuit (IC) package. The IC package can be comprised of a power small outline package (PSOP) that can include one or more gallium nitride field-effect transistors (GaN FET's) for use in power electronics (e.g., power converters, power switching, etc.). Conventional PSOP's include a heat slug or heat spreader that limit the thermal performance of the IC package when used in higher power applications in the range of 3.6-7.0 kW. In addition, as mentioned above, circuit topologies, power output, and package layout are limited due to the single piece heat slug structure.

To improve thermal and electrical performance, the IC package replaces the heat slug with a direct bonded copper (DBC) substrate that includes a ceramic layer and a metal (e.g., copper) layer disposed on each side of the ceramic layer. DBC substrate technology using ceramic and metal materials have excellent thermal and electrical conductivity and good mechanical properties. Conversely, commonly used substrate materials (e.g., glass-epoxy) are insufficient in power electronic modules due to the poor thermal dissipation properties. Still further, with the trend of miniaturizing power electronic modules, DBC substrate technology facilitates the fabrication of the copper layers having a thickness of hundreds of micrometers in one processing step.

A lead frame is attached to a first metal layer of the substrate. In addition, the first metal layer is partitioned into multiple sections where one or more of the multiple sections can be patterned to include complex electrical circuits, such as half-bridge circuits, full-bridge circuits, etc. that include FET's, gate drive IC's, controllers and passive components (e.g., capacitors, resistors, inductors, etc.) to improve the electrical performance of the IC package. Electrical components (e.g., a die including a GaN FET, passive components (e.g., capacitors, inductors, etc.), etc.) can be attached to one or more multiple sections of the first metal layer. The ceramic layer can be made from aluminum oxide (Al₂O₃), aluminum nitride (AlN), silicon nitride (Si₃N₄) or another type of ceramic material having similar thermal and electrical properties. The ceramic layer provides electrical isolation from external components and improves the thermal performance of the IC package. Specifically, the ceramic layer improves the thermal performance of the IC package by approximately 40% over the conventional PSOP IC package operating in the 3.6-7.0 kW range.

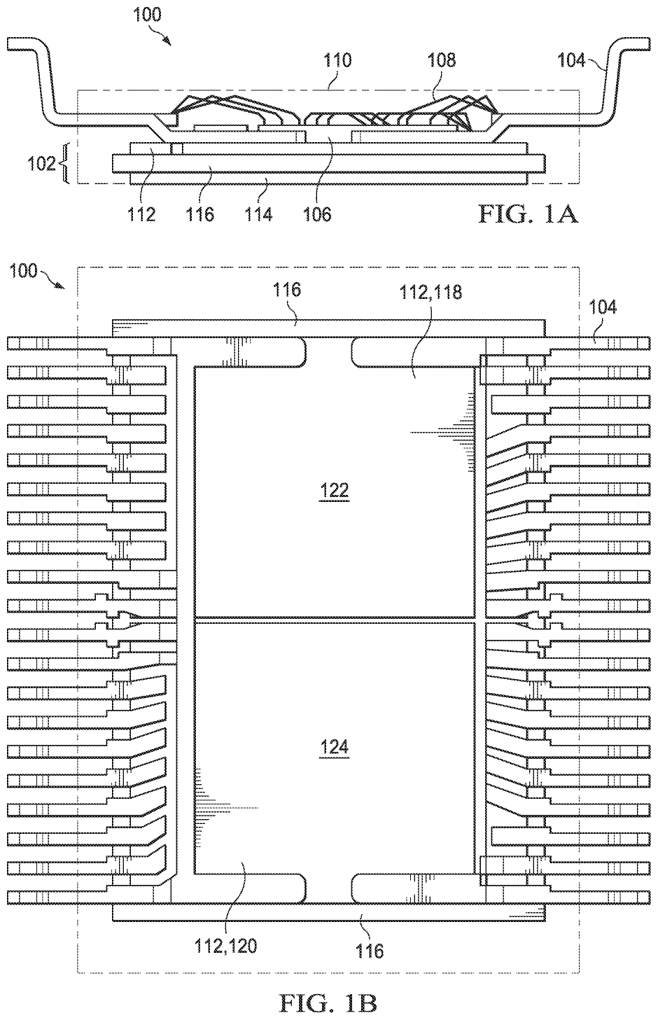

FIGS. 1A and 1B are a plan and side view respectively of an example electronic device (e.g., integrated circuit (IC) package) 100 comprised of a multi-layered substrate (e.g., direct bonded copper (DBC) substrate) 102, a lead frame 104, at least one die 106 (shown in FIG. 1A), and wire bonds 108 (shown in FIG. 1A) connecting the lead frame 104 to the die(s) 106. A mold compound 110 (shown in FIG. 1A) covers all but one surface of the substrate 102, the one surface not covered facing away from the IC package 100, a portion but not all of the lead frame 104, the die(s) 106, and the wire bonds 108. The electronic device 100 can be comprised of a power small outline package (PSOP) that can include one or more gallium nitride field-effect transistors (GaN FET's) for use in power electronics (e.g., power converters, power switching, etc.).

The multi-layered substrate 102 is comprised of a first metal layer 112 and a second metal layer 114. The first and second metal layers 112, 114 are formed from an electrically conductive material (e.g., copper). An intermediate layer 116 made from a ceramic material (e.g., aluminum oxide (Al₂O₃), aluminum nitride (AlN), silicon nitride (Si₃N₄) or another type of ceramic material having similar thermal and electrical properties) is disposed between the first and second metal layers 112, 114.

The first metal layer 112 is partitioned into multiple sections (e.g., two or more sections). For the purpose of illustrative simplicity, in the example illustrated in FIGS. 1A and 1B, the first metal layer is partitioned into two sections. Specifically, the first metal layer 112 is partitioned into a first section 118 and a second section 120. A number of complex circuits, such as half-bridge circuits, full-bridge circuits, etc. that include FET's, gate drive IC's, controllers and passive components (e.g., capacitors, resistors, inductors, etc.) can be patterned on an exposed (first) surface 122 of the first section 118 and on an exposed (first) surface 124 of the second section 120. In addition, electrical components including the die 106, which can include a GaN FET, and passive components (e.g., capacitors, inductors, etc.) can be attached to the surface of each section 118, 120. Thus, in some examples, with the inclusion of the GaN FET, the electronic device 100 can function as a power module for use in power related applications (e.g., power conversion, power switching, etc.). For example, the die 106 on the first section 118 can include a first GaN FET configured to operate as a high-side switch, and the die on the second section 120 can include a second GaN FET configured to operate as a low-side switch.

In another example, the first metal layer 112 can be partitioned into more than two sections, where a first section includes a die having a first GaN FET configured to operate as a high-side switch, a second section that includes a die having a second GaN FET configured to operate as a low-side switch, and a third section can include a die having a control module to drive the electronic device 100. In this scenario, the entire operational unit of the electronic device (e.g., power converter) 100 can be packaged in a single IC package.

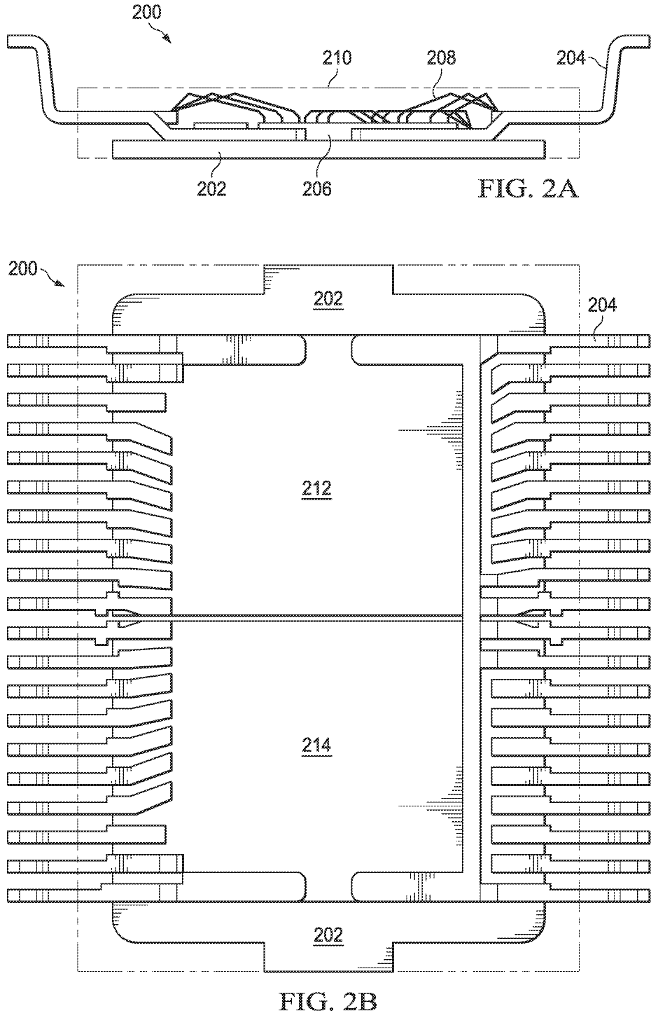

FIGS. 2A and 2B are a plan view and a side view of another electronic device (e.g., integrated circuit (IC) package) 200 that includes a heat slug 202, a lead frame 204, at least one die 206 (shown in FIG. 2A), and wire bonds 208 (shown in FIG. 2A) connecting the lead frame 204 to the die(s) 206. A mold compound 210 (shown in FIG. 2A) covers all but one surface of the heat slug 202, the one surface not covered facing away from the IC package 200, a portion but not all of the lead frame 204, the die(s) 206, and the wire bonds 208.

As mentioned above, complex circuit topologies, power output, and package layout are limited due to the single piece heat slug structure. Thus, in the example illustrated in FIGS. 2A and 2B, the heat slug 202 is partitioned into multiple sections (e.g., two or more sections). For the purpose of illustrative simplicity, in the example illustrated in FIGS. 2A and 2B, the heat slug 202 is partitioned into two sections. Specifically, the heat slug 202 is partitioned into a first section 212 and a second section 214. Thus, similarly to the electronic device 100 described above, the electronic device 200 can function as a power module where the first section 212 can include a first GaN FET configured to operate as a high-side switch, and the second section 120 can include a second GaN FET configured to operate as a low-side switch. In this example, however, thermal performance in integrated circuit (IC) packages for power related applications that include a heat slug are dependent on the thermal properties of the heat slug 202. As described above, reducing the thermal resistance of the IC package below a desired value is difficult due to the poor thermal properties of the heat slug.

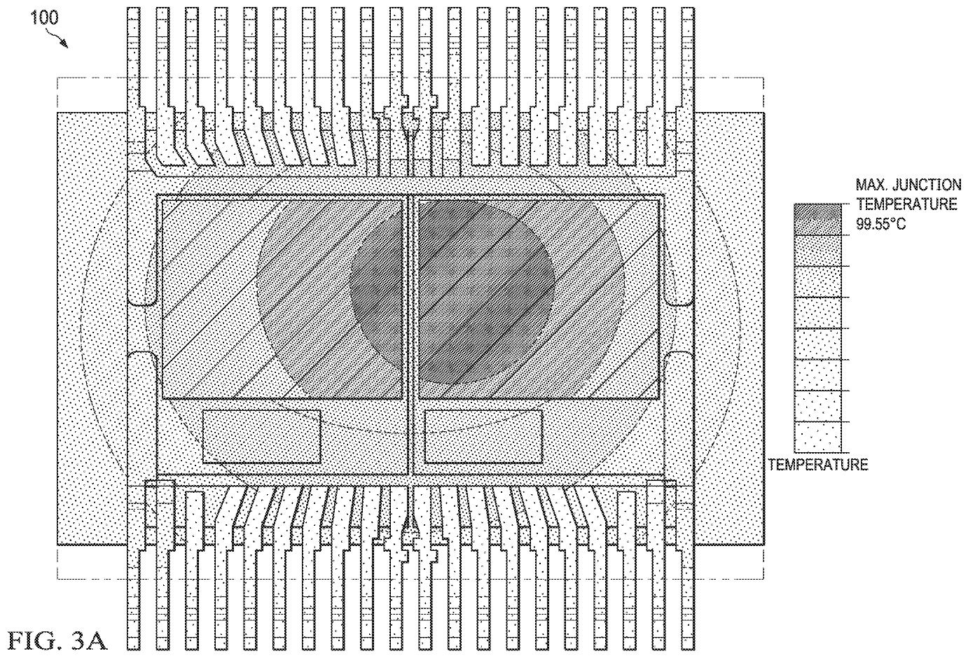

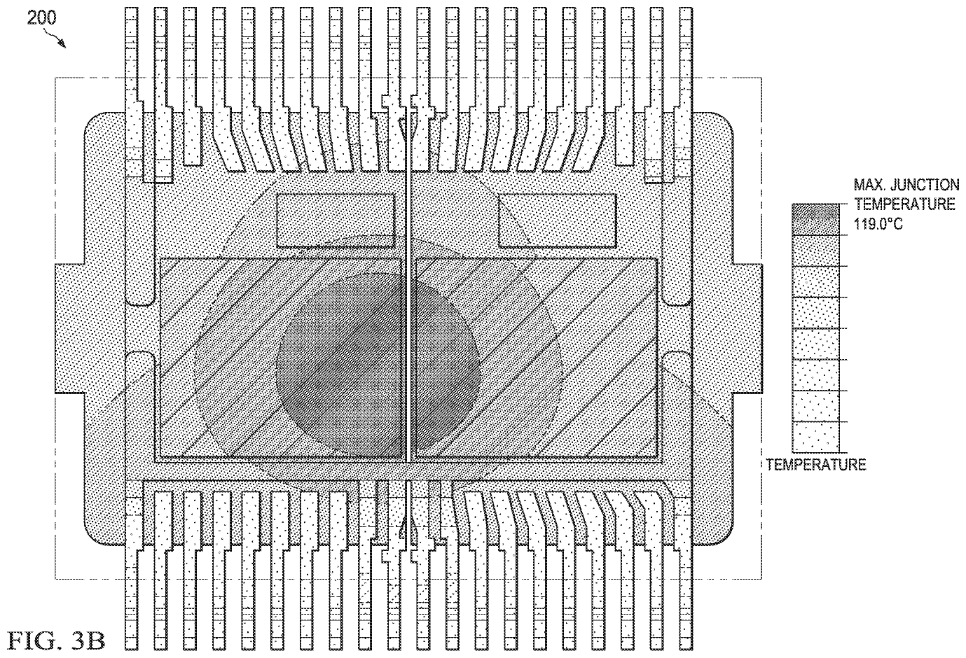

Specifically, FIGS. 3A and 3B illustrate the thermal performance of the example electronic device 100 illustrated in FIGS. 1A and 1B and the example electronic device 200 illustrated in FIGS. 2A and 2B respectively. As illustrated in the legend, the maximum junction temperature (temperature at the junction between the DBC substrate 102 and the die 106) of the DBC substrate electronic device 100 is 99.55° C. The maximum junction temperature (temperature at the junction between the heat slug 202 and the die 206) of the heat slug electronic device 200 is 119.0° C. In addition, the thermal resistance (Rₜₕ) of the DBC substrate electronic device 100 is 0.86 K/W (per module) and the thermal resistance (Rₜₕ) of the DBC substrate electronic device 200 is 1.35 K/W (per module). The thermal resistance is defined as the change in die junction temperature from the die to the bottom of the IC package. The lower the thermal resistance the better the electronic device will dissipate heat. Thus, IC packages with a lower thermal resistance can be fabricated to include additional circuits, dies, FETS, components, etc. to deliver more power since the additional heat can be dissipated.

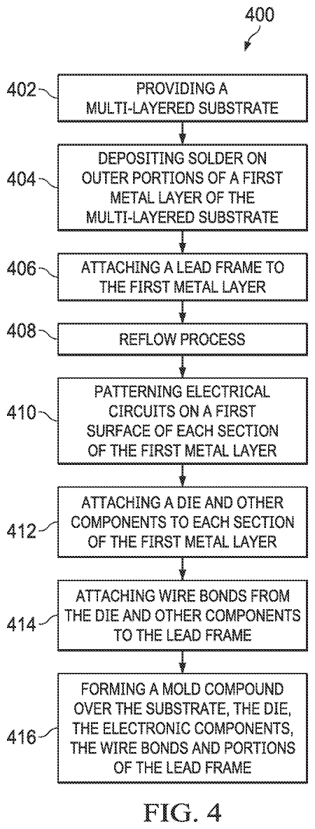

FIG. 4 illustrates a fabricating process 400 of an electronic device in connection with the electronic device 100 illustrated in FIGS. 1A and 1B. Though depicted sequentially as a matter of convenience, at least some of the actions shown can be performed in a different order and/or performed in parallel. Alternatively, some implementations may perform only some of the actions shown. Still further, although the example illustrated in FIG. 4 is an example method illustrating the example configuration of FIGS. 1A and 1B, other methods and configurations are possible.

Referring to FIG. 4, the fabricating process 400 begins at 402 with a multi-layered substrate (e.g., substrate 102) that includes an intermediate layer (e.g., ceramic intermediate layer 116), a first metal (e.g., copper) layer (e.g., metal layer 112) deposited on one side of the ceramic layer and a second metal (e.g., copper) layer (e.g., metal layer 114) deposited on an opposite side of the intermediate layer. The first metal layer can be partitioned into two of more sections (e.g., first section 118, second section 120). The first and second metal layers can be bonded to the intermediate layer via a direct bonding process. During the bonding process, thin transition layers are created between metal and intermediate layer (e.g., ceramic layer), which is formed by an oxygen bridge between the two materials. To ensure a strong bond and tight contact between the materials, the metal layer can be changed into a liquid state via a melting process (e.g., gas-metal eutectic process). The metal liquid surface will occupy the intermediate layer surface and after a cooling process, the metal layer is adhered to the intermediate layer.

At 404, solder is deposited via a soldering process (e.g., paste printing, screen printing, etc.) on outer portions of an exposed (first) surface (e.g., first surface 122, 124) of the first metal layer. At 406, a lead frame (e.g., lead frame 104) is attached to the first surface of the first metal layer at locations (i.e., outer portions) where the solder is printed or deposited. At 408, the electronic device undergoes a reflow process via a reflow oven to melt the solder at a specific temperature to form a tight, conductive bond between the first metal layer and the lead frame. At 410, electrical circuits are patterned on the first surface of each section of the first metal layer. At 412, a die (e.g., die 106) and other electronic components are attached to the first surface each section of the first metal layer. At 414, wire bonds (e.g., wire bonds 108) are attached from the die and other electronic components to the lead frame. At 416, a mold compound (e.g., mold compound 110) is formed over the multi-layered substrate die, the wire bonds, and portions of the lead frame and cured during a curing process thereby forming the electronic device. The mold compound is formed such that the mold compound encapsulates the substrate the die, the other electronic components, and the wire bonds. The mold compound can be made from an epoxy or epoxy blends, silicone, polyimide, etc.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a multi-layered substrate comprised of a first metal layer, a second metal layer, and an intermediate layer disposed between the first metal layer and the second metal layer, the first metal layer being partitioned into sections, each of the sections having a first surface and electrical circuits patterned onto the first surface;
a lead frame attached to the first metal layer; and
a die attached to the first surface of each of the sections of the first metal layer.

2. The electronic device of claim 1, wherein the die for each of the sections of the first metal layer includes a gallium nitride field-effect transistor.

3. The electronic device of claim 2, wherein the sections comprise a first section and a second section, wherein the gallium nitride field-effect transistor for the first section is configured to operate as a high-side gallium nitride field-effect transistor and the gallium nitride field-effect transistor for the second section is configured to operate as a low-side gallium nitride field-effect transistor.

4. The electronic device of claim 1, wherein the sections comprise a first section, a second section, and a third section, the die attached to the first section includes a first gallium nitride field-effect transistor, the die attached to the second section includes a second gallium nitride field-effect transistor, and the third section includes a control module to drive the electronic device.

5. The electronic device of claim 4, wherein the first gallium nitride field-effect transistor of the die attached to the first section is configured to operate as a high-side gallium nitride field-effect transistor and the second gallium nitride field-effect transistor of the die attached to the second section is configured to operate as a low-side gallium nitride field-effect transistor.

6. The electronic device of claim 1, wherein the first metal layer and the second metal layer are comprised of copper.

7. The electronic device of claim 6, wherein the intermediate layer is comprised of a ceramic material.

8. The electronic device of claim 7, wherein the ceramic material is one of aluminum oxide, aluminum nitride, and silicon nitride.

9. A power converter comprising:
a multi-layered substrate comprised of a first metal layer, a second metal layer, and an intermediate layer disposed between the first metal layer and the second metal layer, the first metal layer being partitioned into a first section having a first surface and a second section having a first surface;
electrical circuits patterned onto the first surface of the first section and the first surface of the second section;
a lead frame attached to outer portions of the first metal layer; and
a die attached to the first surface of the first section and the first surface of the second section.

10. The power converter of claim 9, wherein the die attached to the first section of the first metal layer includes a gallium nitride field-effect transistor configured to operate as a high-side gallium nitride field-effect transistor and the die attached to the second section of the first metal layer includes a gallium nitride field-effect transistor configured to operate as a low-side gallium nitride field-effect transistor.

11. The power converter of claim 9, wherein the first metal layer is partitioned into a third section, wherein electrical circuits are patterned onto a first surface of the third section, and wherein a die is attached to the first surface of the third section.

12. The power converter of claim 11, wherein the die attached to the first section includes a first gallium nitride field-effect transistor, the die attached to the second section includes a second gallium nitride field-effect transistor, and the die attached to the third section includes a control module to drive the power converter.

13. The power converter of claim 12, wherein the first gallium nitride field-effect transistor attached to the die of the first section is configured to operate as a high-side gallium nitride field-effect transistor and the second gallium nitride field-effect transistor attached to the die for the second section is configured to operate as a low-side gallium nitride field-effect transistor.

14. The power converter of claim 13, wherein the first metal layer and the second metal layer are comprised of copper.

15. The power converter of claim 14, wherein the intermediate layer is comprised of a ceramic material.

16. The power converter of claim 15, wherein the ceramic material is one of aluminum oxide, aluminum nitride, and silicon nitride.

17. A method comprising:
providing a multi-layered substrate, the multi-layered substrate having a first metal layer, a second metal layer, and an intermediate layer disposed between the first metal layer and the second metal layer, the first metal layer partitioned into sections;
attaching a lead frame to outer portions of the first metal layer;
attaching a die to a first surface of each of the partitioned sections of the first metal layer;
attaching wire bonds from the die attached to each of the partitioned sections to the lead frame; and
forming a mold compound over portions of the lead frame, the multi-layered substrate, each die, and the wire bonds.

18. The method of claim 17, wherein the sections comprise a first section, a second section, and a third section, the die of the first section including a first gallium nitride field-effect transistor, the die of the second section including a second gallium nitride field-effect transistor, and the third section including a control module.

19. The method of claim 18, wherein the first gallium nitride field-effect transistor of the die of the first section is configured to operate as a high-side gallium nitride field-effect transistor and the second gallium nitride field-effect transistor of the die for the second section is configured to operate as a low-side gallium nitride field-effect transistor.

20. The method of claim 19, wherein the first metal layer and the second metal layer are comprised of copper and the intermediate layer is comprised of a ceramic material.
